(19) United States
(12) Patent Application Publication
(10) Pub. No.: US 2026/0140146 A1
(43) Pub. Date: May 21, 2026

(54) CURRENT SENSING COIL

(71) Applicant: INDUSTRIAL TECHNOLOGY RESEARCH INSTITUTE, Hsinchu (TW)

(72) Inventors: UMA SANKAR ROUT, Hsinchu (TW); CHIH-CHIANG WU, Hsinchu (TW)

(21) Appl. No.: 19/004,543

(22) Filed: Dec. 30, 2024

(30) Foreign Application Priority Data
Nov. 19, 2024 (TW) 113144519

(51) Int. Cl. G01R 15/18

(52) U.S. Cl. CPC G01R 15/181

(57) ABSTRACT

A current sensing coil includes a shielding layer, a sensing coil and a short-circuited coil. The shielding layer has a central hole. The sensing coil is disposed within the central hole. The short-circuited coil is also disposed within the central hole. The number of turns of the sensing coil is greater than the number of turns of the short-circuited coil. The sensing coil surrounds the short-circuited coil, such that the short-circuited coil is disposed inside the sensing coil.

### CROSS REFERENCE TO RELATED APPLICATION

All related applications are incorporated by reference. The present application is based on, and claims priority from, Taiwan Application Serial Number 113144519, filed on Nov. 19, 2024, the disclosure of which is hereby incorporated by reference herein in its entirety.

### TECHNICAL FIELD

The technical field relates to a sensing coil, in particular to a current sensing coil.

### BACKGROUND

With the advancement of technology, the demand for current-sensing technologies across various industries, such as electric vehicles and smart grids, has been continuously increasing. Consequently, how to improve existing current-sensing technologies to meet the requirements for high precision, wide bandwidth, and reliability in diverse applications has become an urgent issue.

Most currently available Rogowski coils adapt a single-coil design. As a result, these current-sensing coils must either limit bandwidth to achieve high sensitivity or limit sensitivity to achieve wide bandwidth. Thus, these current sensing coils are usually improved in only sensitivity or bandwidth, but not both simultaneously.

### SUMMARY

One embodiment of the disclosure discloses a current sensing coil, which includes a shielding layer, a sensing coil and a short-circuited coil. The shielding layer has a central hole. The sensing coil is disposed within the central hole. The short-circuited coil is disposed within the central hole. The number of turns of the sensing coil is greater than the number of turns of the short-circuited coil. The sensing coil surrounds the short-circuited coil, such that the short-circuited coil is disposed inside the sensing coil.

Another embodiment of the disclosure discloses a current sensing coil, which includes a shielding layer, a sensing coil and a short-circuited coil. The shielding layer includes a central hole. The sensing coil is disposed within the central hole. The sensing coil includes a first sensing coil set and a second sensing coil set, and the first sensing coil set and the second sensing coil set are intertwined in opposite directions, The short-circuited coil is disposed within the central hole. The front end of the first sensing coil set and the front end of the second sensing coil set are connected to each other, and the rear end of the first sensing coil set is connected to the rear end of the second sensing coil set.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The disclosure will become more fully understood from the detailed description given herein below and the accompanying drawings which are given by way of illustration only, and thus are not limitative of the disclosure and wherein:

FIG. 1 is a perspective view of a current sensing coil in accordance with one embodiment of the disclosure.

FIG. 2 is a perspective view of a shielding layer of the current sensing coil in accordance with one embodiment of the disclosure.

FIG. 3 is a perspective view of a sensing coil of the current sensing coil in accordance with one embodiment of the disclosure.

FIG. 4 is a first partial enlargement view of the sensing coil of the current sensing coil in accordance with one embodiment of the disclosure.

FIG. 5 is a second partial enlargement view of the sensing coil of the current sensing coil in accordance with one embodiment of the disclosure.

FIG. 6 is a schematic view of a reverse-parallel structure of the current sensing coil in accordance with one embodiment of the disclosure.

FIG. 7 is a perspective view of a short-circuited coil of the current sensing coil in accordance with one embodiment of the disclosure.

FIG. 8 is a first partial enlargement view of the short-circuited coil of the current sensing coil in accordance with one embodiment of the disclosure.

FIG. 9 is a second partial enlargement view of the short-circuited coil of the current sensing coil in accordance with one embodiment of the disclosure.

FIG. 10 is a perspective view of a current sensing coil in accordance with another embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing. It should be understood that, when it is described that an element is “coupled” or “connected” to another element, the element may be “directly coupled” or “directly connected” to the other element or “coupled” or “connected” to the other element through a third element. In contrast, it should be understood that, when it is described that an element is “directly coupled” or “directly connected” to another element, there are no intervening elements.

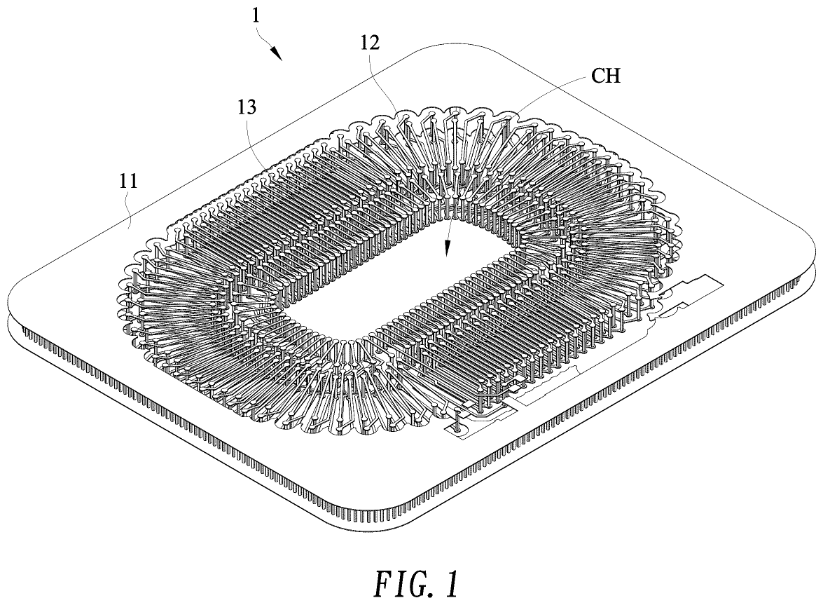

Please refer to FIG. 1, which illustrates a perspective view of a current sensing coil in accordance with one embodiment of the disclosure. As shown in FIG. 1, the current sensing coil 1 includes a shielding layer 11, a sensing coil 12 and a short-circuited coil 13.

The shielding layer 11 has a central hole CH.

The short-circuited coil 13 is disposed within the central hole CH.

The sensing coil 12 is also disposed within the central hole CH. The sensing coil 12 surrounds the short-circuited coil 13, such that the short-circuited coil 13 is disposed inside the sensing coil 12 to form a concentric structure. The shielding layer 11, the sensing coil 12 and the short-circuited coil 13 can be on the same plane. In another embodiment, the shielding layer 11, the sensing coil 12 and the short-circuited coil 13 can be on different planes.

Besides, the number of turns of the sensing coil 12 is greater than the number of turns of the short-circuited coil 13. For example, the number of turns of the sensing coil 12 is 1.3 to 2.5 times the number of turns of the short-circuited coil 13. For example, the number of turns of the sensing coil 12 is 1.5 to 2.2 times the number of turns of the short-circuited coil 13. For example, the number of turns of the sensing coil 12 is 1.7 to 2 times the number of turns of the short-circuited coil 13. For example, the number of turns of the sensing coil 12 is 169, and the number of turns of the short-circuited coil 13 is 93. For example, the number of turns of the sensing coil 12 is 189, and the number of turns of the short-circuited coil 13 is 90. For example, the number of turns of the sensing coil 12 is 218, and the number of turns of the short-circuited coil 13 is 95.

The aforementioned coil structure design are based on Rogowski coil and has the concentric structure formed by arranging the sensing coil 12 and the short-circuited coil 13 within the shielding layer 11. In addition, the sensing coil 12 is positioned on the outer ring of the concentric structure and the short-circuited coil 13 is positioned on the inner ring of the concentric structure. The short-circuited coil 13 positioned on the inner ring is a low-impedance coil with fewer turns, which can effectively enhance the bandwidth. The sensing coil 12 positioned on the outer ring is a high-sensitivity coil with more turns, which can effectively improve sensitivity.

Thus, the current sensing coil 1 can simultaneously enhance both bandwidth and sensitivity in order to simultaneously achieve high bandwidth and high sensitivity. Additionally, the high-sensitivity sensing coil 12 can achieve precise current measurement ranging from 1A to 1000A, ensuring linear and accurate measurement results. The low-impedance short-circuited coil 13 improves the response capability to transient effects in order to achieve fast and accurate measurement of dynamic current fluctuations.

The embodiment just exemplifies the disclosure and is not intended to limit the scope of the disclosure. Any equivalent modification and variation according to the spirit of the disclosure is to be also included within the scope of the following claims and their equivalents.

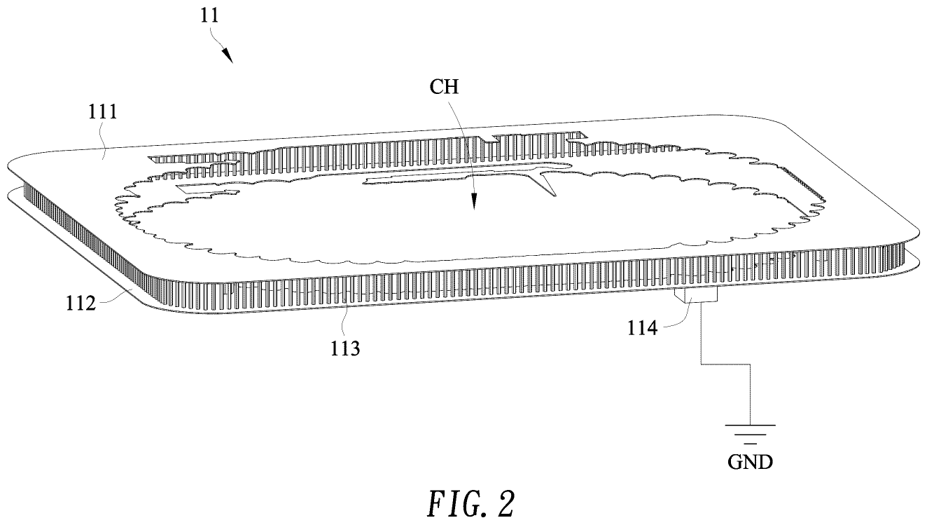

Please refer to FIG. 2, which illustrates a perspective view of a shielding layer of the current sensing coil in accordance with one embodiment of the disclosure. As shown in FIG. 2, the shielding layer 11 includes an upper circuit board 111, a lower circuit board 112, and a plurality of connecting poles 113. The upper circuit board 111 is connected to the lower circuit board 112 via these connecting poles 113.

The connecting poles 113 are hollow, forming a plurality of through holes (vias). These through holes effectively create a shielding wall around the sensing coil 12 and the short-circuited coil 13, which can achieve noise isolation effect.

Additionally, the shielding layer 11 includes a grounding point 114. The shielding layer 11 is connected to ground GND via this single grounding point 114 in order to effectively eliminate ground loop noise. The aforementioned shielding wall and single-point grounding structure form an efficient shielding mechanism, which can significantly optimize the electromagnetic compatibility (EMC) of adjacent current path.

The embodiment just exemplifies the disclosure and is not intended to limit the scope of the disclosure. Any equivalent modification and variation according to the spirit of the disclosure is to be also included within the scope of the following claims and their equivalents.

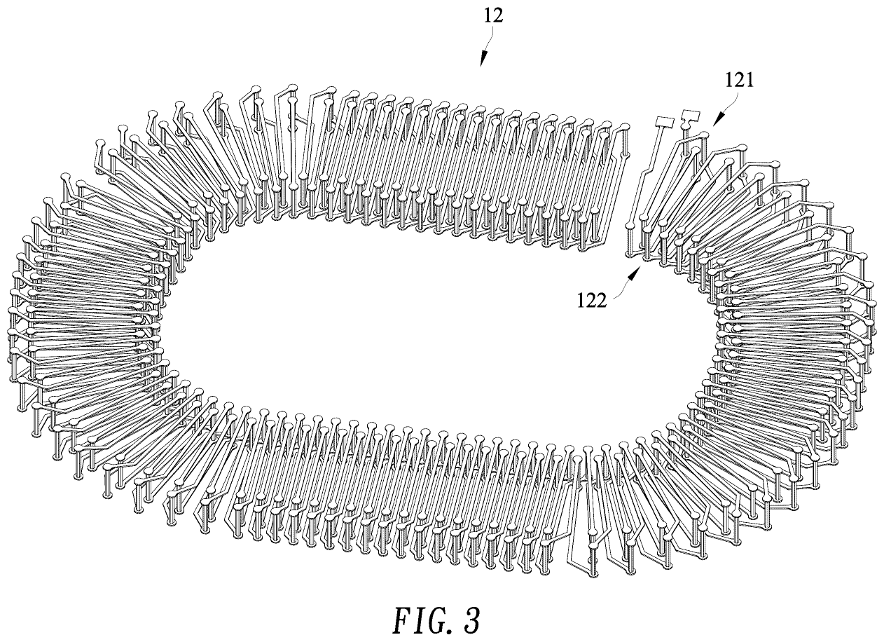

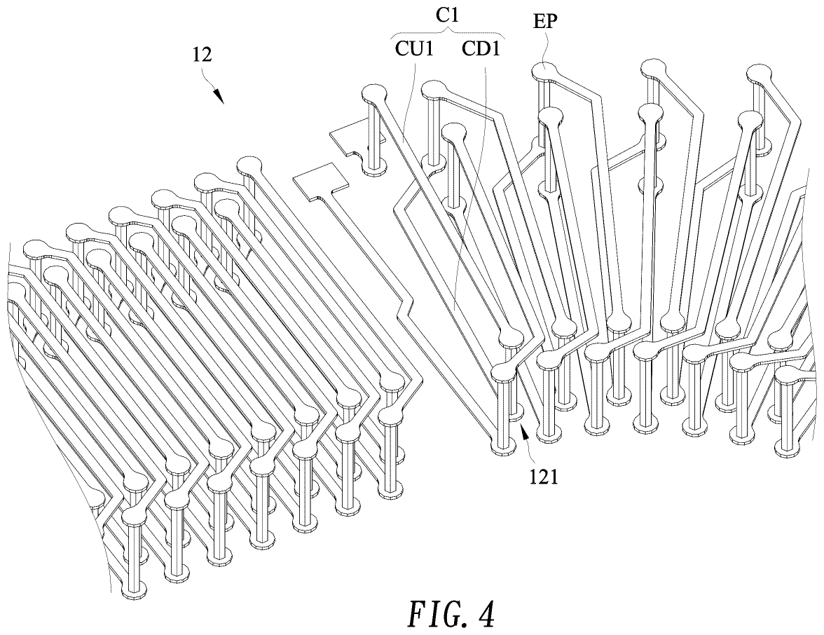

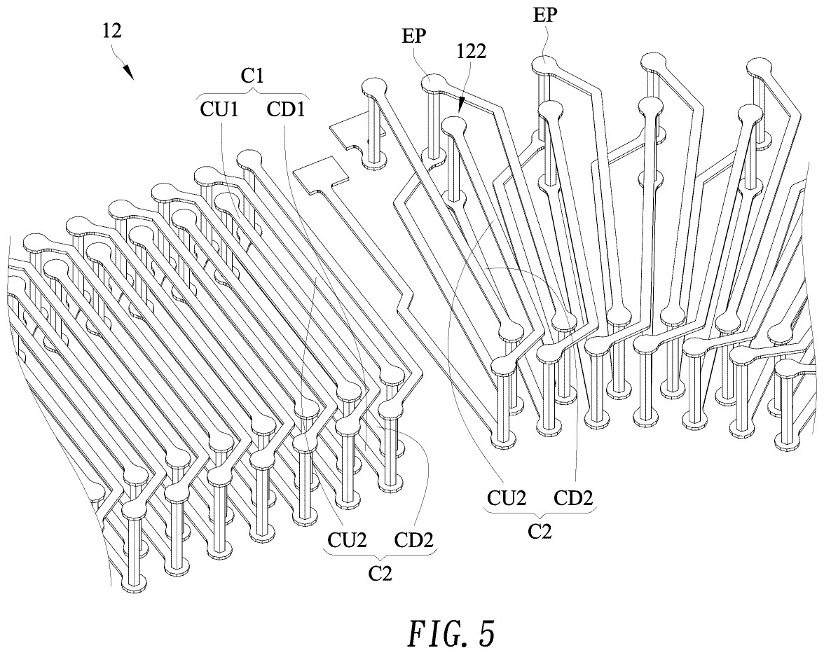

Please refer to FIG. 3, FIG. 4, and FIG. 5. FIG. 3 illustrates a perspective view of a sensing coil of the current sensing coil in accordance with one embodiment of the disclosure. FIG. 4 illustrates a first partial enlargement view of the sensing coil of the current sensing coil in accordance with one embodiment of the disclosure. FIG. 5 illustrates a second partial enlargement view of the sensing coil of the current sensing coil in accordance with one embodiment of the disclosure. As shown in FIG. 3, the sensing coil 12 includes a first sensing coil set 121 and a second sensing coil set 122. The first sensing coil set 121 and the second sensing coil set 122 are connected to each other. The first sensing coil set 121 and the second sensing coil set 122 are intertwined in opposite directions to reduce stray capacitance. Further, the front ends of the first sensing coil set 121 and the second sensing coil set 122 are connected to each other, and the rear ends of the first sensing coil set 121 and the second sensing coil set 122 connected to each other. The first sensing coil set 121 does not contact the second sensing coil set 122 except the rear end thereof.

As shown in FIG. 4, the first sensing coil set 121 includes a plurality of first coil units C1 and a plurality of electrical connecting poles EP, which are connected in series to form an interconnected and efficient current sensing configuration. Each first coil unit C1 includes a first upper conductor CU1 and a first lower conductor CD1. The first upper conductor CU1 is connected to the first lower conductor CD1 via an electrical connecting pole EP.

As shown in FIG. 5, the second sensing coil set 122 includes a plurality of second coil units C2 and a plurality of electrical connecting poles EP, which are connected in series to form an interconnected and efficient current sensing configuration. Each second coil unit C2 includes a second upper conductor CU2 and a second lower conductor CD2. The second upper conductor CU2 is connected to the second lower conductor CD2 via an electrical connecting pole EP.

The first upper conductor CU1 or the first lower conductor CD1 of the first coil unit C1 at the front end of the first sensing coil set 121 is connected to the second upper conductor CU2 or the second lower conductor CD2 of the second coil unit C2 at the front end of the second sensing coil set 122. In another embodiment, one of the first upper conductor CU1 or the first lower conductor CD1 of the first coil unit C1 at the front end of the first sensing coil set 121 is connected to the system's ground or another reference point. One of the second upper conductor CU2 or the second lower conductor CD2 of the second coil unit C2 at the front end of the second sensing coil set 122 is connected to the system's ground or another reference point.

The first upper conductor CU1 or the first lower conductor CD1 of the first coil unit C1 at the rear end of the first sensing coil set 121 is connected to the second upper conductor CU2 or the second lower conductor CD2 of the second coil unit C2 at the rear end of the second sensing coil set 122. In another embodiment, one of the first upper conductor CU1 or the first lower conductor CD1 of the first coil unit C1 at the rear end of the first sensing coil set 121 is connected to the system's ground or another reference point. One of the second upper conductor CU2 or the second lower conductor CD2 of the second coil unit C2 at the rear end of the second sensing coil set 122 is connected to the system's reference point or ground.

The first upper conductor CU1 or first lower conductor CD1 of the first coil unit C1 at the rear end of the first sensing coil set 121 is connected to the second upper conductor CU2 or second lower conductor CD2 of the second coil unit C2 at the rear end of the second sensing coil set 122.

Through the structural design of the first sensing coil set 121 and the second sensing coil set 122, any first coil unit C1 is separated from another first coil unit C1 by at least one second coil unit C2. The first upper conductor CU1 of any first coil unit C1 is separated from the first upper conductor CU1 of another first coil unit C1 by the second upper conductor CU2 of at least one second coil unit C2. Similarly, the first lower conductor CD1 of any first coil unit C1 is separated from the first lower conductor CD1 of another first coil unit C1 by the second lower conductor CD2 of at least one second coil unit C2.

Thus, the first upper conductor CU1 of each first coil unit C1 is adjacent to the second upper conductor CU2 of at least one second coil unit C2 and is substantially located on the same plane. Likewise, the first lower conductor CD1 of each first coil unit C1 is adjacent to the second lower conductor CD2 of at least one second coil unit C2 and is substantially located on the same plane.

Similarly, any second coil unit C2 is separated from another second coil unit C2 by at least one first coil unit C1. The second upper conductor CU2 of any second coil unit C2 is separated from the second upper conductor CU2 of another second coil unit C2 by the first upper conductor CU1 of at least one first coil unit C1. The second lower conductor CD2 of any second coil unit C2 is separated from the second lower conductor CD2 of another second coil unit C2 by the first lower conductor CD1 of at least one first coil unit C1.

Thus, the second upper conductor CU2 of each second coil unit C2 is adjacent to the first upper conductor CU1 of at least one first coil unit C1 and is substantially located on the same plane. Similarly, the second lower conductor CD2 of each second coil unit C2 is adjacent to the first lower conductor CD1 of at least one first coil unit C1 and is substantially located on the same plane.

Via the aforementioned structural design, the first sensing coil set 121 and the second sensing coil set 122 can be intertwined in opposite directions and connected to each other.

The embodiment just exemplifies the disclosure and is not intended to limit the scope of the disclosure. Any equivalent modification and variation according to the spirit of the disclosure is to be also included within the scope of the following claims and their equivalents.

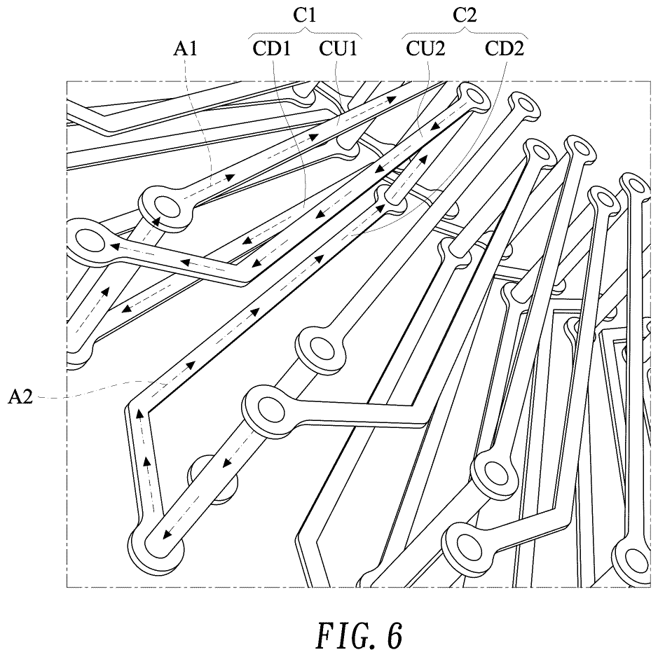

Please refer to FIG. 6, which illustrates a schematic view of a reverse-parallel structure of the current sensing coil in accordance with one embodiment of the disclosure. As shown in FIG. 6, the current direction of the first upper conductor CU1 of each first coil unit C1 is opposite to the current direction of the first lower conductor CD1 of the same first coil unit C1, as indicated by the arrow A1 (dashed line) shown in FIG. 6. The current direction of the first upper conductor CU1 of the first coil unit C1 flows outward toward the outer ring, while the current direction of the first lower conductor CD1 of the first coil unit C1 flows inward toward the inner ring. Alternatively, the current direction of the first upper conductor CU1 of the first coil unit C1 flows inward toward the inner ring, while the current direction of the first lower conductor CD1 of the first coil unit C1 flows outward toward the outer ring.

The current direction of the second upper conductor CU2 of each second coil unit C2 is opposite to the current direction of the second lower conductor CD2 in the same second coil unit C2, as indicated by the arrow A2 (dotted chain line) shown in FIG. 6. The current direction of the second upper conductor CU2 of the second coil unit C2 flows inward toward the inner ring, while the current direction of the second lower conductor CD2 of the second coil unit C2 flows outward toward the outer ring. Alternatively, the current direction of the second upper conductor CU2 of the second coil unit C2 flows outward toward the outer ring, while the current direction of the second lower conductor CD2 of the second coil unit C2 flows inward toward the inner ring.

The current direction of the first upper conductor CU1 of each first coil unit C1 is opposite to the current direction of the second upper conductor CU2 of the adjacent second coil unit C2, as indicated by the arrows A1 and A2 shown in FIG. 6. The current direction of the first upper conductor CU1 of the first coil unit C1 flows outward toward the outer ring, while the current direction of the second upper conductor CU2 adjacent to the first upper conductor CU1 flows inward toward the inner ring. Alternatively, the current direction of the first upper conductor CU1 of the first coil unit C1 flows inward toward the inner ring, while the current direction of the second upper conductor CU2 adjacent to the first upper conductor CU1 flows outward toward the outer ring.

Similarly, the current direction of the first lower conductor CD1 of each first coil unit C1 is opposite to the current direction of the second lower conductor CD2 of the adjacent second coil unit C2. The current direction of the first lower conductor CD1 of the first coil unit C1 flows inward toward the inner ring, while the current direction of the second lower conductor CD2 of the adjacent second coil unit C2 flows outward toward the outer ring. Alternatively, the current direction of the first lower conductor CD1 of the first coil unit C1 flows outward toward the outer ring, while the current direction of the second lower conductor CD2 adjacent to the first lower conductor CD1 flows inward toward the inner ring.

Through the above reverse-parallel structure, the signal transmission directions between any two adjacent conductors are opposite, which can significantly reduce the parasitic capacitance of the sensing coil 12 in order to enhance the performance of the sensing coil 12 in high-frequency applications. Meanwhile, the signal transmission directions between the upper conductor and the lower conductor corresponding thereto are also opposite, which can significantly decrease stray capacitance in order to make sure that the sensing coil 12 can maintain high accuracy and sensitivity even under strong electromagnetic interference.

The aforementioned conductors (first upper conductor CU1, first lower conductor CD1, second upper conductor CU2, and second lower conductor CD2) may refer to traces, conductive sheets, or various metal conductive components (e.g., copper, aluminum, various alloys, etc.). Taking traces as an example, the capacitance between two parallel traces (which are adjacent to each other and substantially located on the same plane, with the same current direction) can be expressed by Equation (1) given below:

$$Ca = \frac{{ε}_{0} {ε}_{γ} \cdot W \cdot L}{d} \qquad ( 1 )$$

In Equation (1), Ca stands for the capacitance value (F) between two parallel traces, co stands or the permittivity of free space; Ey represents the relative permittivity of the dielectric material; W stands for the trace width (m); L stands for the length of the trace (m); d stands for the distance between the traces (m).

Based on the reverse-parallel structure of this embodiment, the signal transmission directions between any two adjacent traces are opposite, resulting in a different interaction of the electric fields between the two traces. The electric fields of the two traces partially cancel each other out. The capacitance between two traces in the reverse-parallel structure (where the two traces are adjacent to each other, substantially located in the same plane, but with opposite current directions) can be expressed by Equation (2) given below:

$$Cb \approx K \cdot Ca \qquad ( 2 )$$

In Equation (2), Cb represents the capacitance value (F) between two traces based on the reverse-parallel structure; K is a factor less than 1 (e.g., 0.55 to 0.8) related to the shape characteristics of the traces, which may include the relative permittivity of the dielectric material, trace width, coil length, the distance between the trace and the busbar, etc.

For example, the thickness of the circuit board is 2 mm; the trace width of the short-circuited coil 13 is 0.203 mm; the coil length of the short-circuited coil 13 is 380.88 mm; the distance between the short-circuited coil 13 and the busbar is 1 mm; the trace width of the sensing coil 12 is 0.203 mm; the coil length of the sensing coil 12 is 695.52 mm; the distance between the sensing coil 12 and the busbar is 3.307 mm; ε0=8.85×10⁻¹² F/m; and ε_{γ}=4 (the relative permittivity of typical PCB materials).

According to Equation (1), Ca can be calculated via Equation (3) given below:

$$Ca = \frac{8.85 \times {10}^{- 12} \times 4 \times 0.203 \times {10}^{- 3} \times 380.88 \times 1 {0}^{- 3}}{1 \times 1 {0}^{- 3}} = 2.73 \times 1 {0}^{- 12} F \qquad ( 3 )$$

According to Equation (1), Cb can be calculated via Equation (4) given below:

$$Cb = \frac{8.85 \times {10}^{- 12} \times 4 \times 0.203 \times {10}^{- 3} \times 695.2 \times 1 {0}^{- 3}}{3.307 \times 1 {0}^{- 3}} = 1.51 \times 1 {0}^{- 12} F \qquad ( 4 )$$

As a result, according to Equation (2), K can be calculated via Equation (5) given below:

$$K \approx \frac{Cb}{Ca} = 0.55 \qquad ( 5 )$$

In addition, the aforementioned reverse-parallel structure can further enhance the noise isolation effect of the sensing coil 12 with a view to reducing electromagnetic interference and thereby improving the overall performance of the current sensing coil 1.

The embodiment just exemplifies the disclosure and is not intended to limit the scope of the disclosure. Any equivalent modification and variation according to the spirit of the disclosure is to be also included within the scope of the following claims and their equivalents.

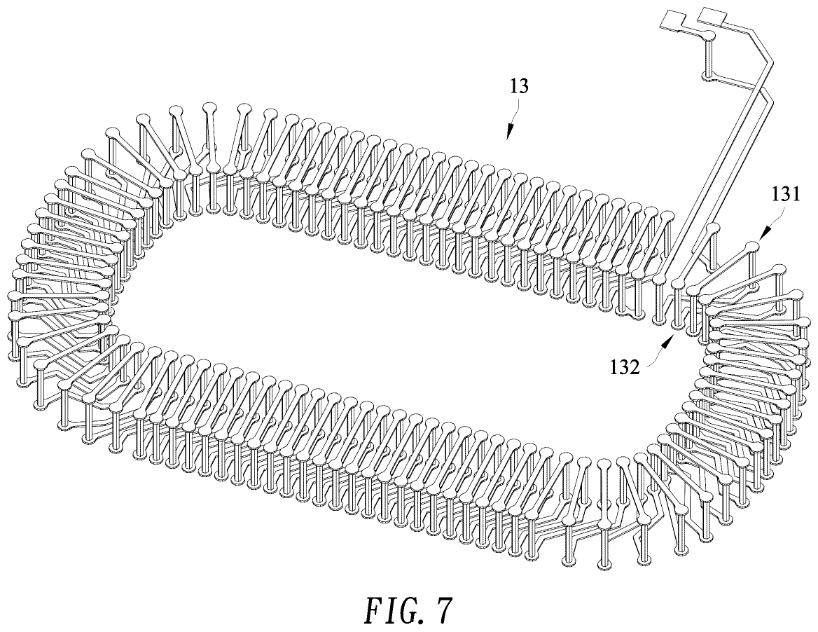

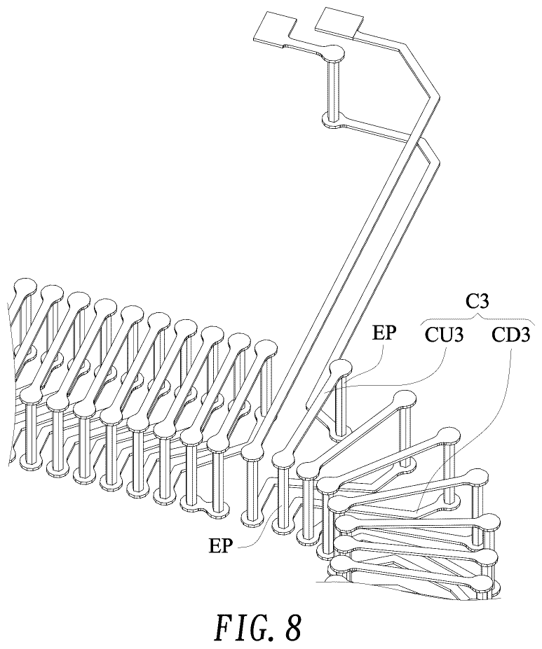

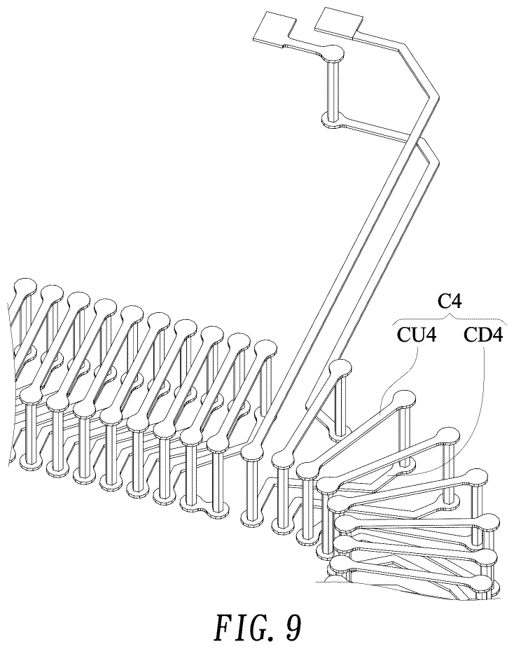

Please refer to FIG. 7, FIG. 8, and FIG. 9. FIG. 7 illustrates a perspective view of a short-circuited coil of the current sensing coil in accordance with one embodiment of the disclosure. FIG. 8 illustrates a first partial enlargement view of the short-circuited coil of the current sensing coil in accordance with one embodiment of the disclosure. FIG. 9 illustrates a second partial enlargement view of the short-circuited coil of the current sensing coil in accordance with one embodiment of the disclosure. As shown in FIG. 7, the short-circuited coil 13 includes a first short-circuited coil set 131 and a second short-circuited coil set 132. The first short-circuited coil set 131 and the second short-circuited coil set 132 are intertwined in opposite directions. The front ends of the first short-circuited coil set 131 and the second short-circuited coil set 132 are connected to each other, while the rear ends of the first short-circuited coil set 131 and the second short-circuited coil set 132 are connected to each other in order to form a cohesive low-impedance structure.

As shown in FIG. 8, the first short-circuited coil set 131 includes a plurality of third coil units C3 and a plurality of electrical connecting poles EP, which are connected in series to form an interconnected low-impedance structure. Each third coil unit C3 includes a third upper conductor CU3 and a third lower conductor CD3. The third upper conductor CU3 is connected to the third lower conductor CD3 via one electrical connecting pole EP.

As shown in FIG. 9, the second short-circuited coil set 132 includes a plurality of fourth coil units C4 and a plurality of electrical connecting poles EP, which are connected in series to form an interconnected low-impedance structure. Each fourth coil unit C4 includes a fourth upper conductor CU4 and a fourth lower conductor CD4. The fourth upper conductor CU4 is connected to the fourth lower conductor CD4 via an electrical connecting pole EP. One of the third upper conductor CU3 and the third lower conductor CD3 of the third coil unit C3 at the front end of the first short-circuited coil set 131 is connected to One of the fourth upper conductor CU4 and the fourth lower conductor CD4 of the fourth coil unit C4 at the front end of the first short-circuited coil set 131, either directly or through an electrical connecting pole EP and/or a conductor.

The third upper conductor CU3 or the third lower conductor CD3 of the third coil unit C3 at the rear end of the first short-circuited coil set 131 is connected to the fourth upper conductor CU4 or the fourth lower conductor CD4 of the fourth coil unit C4 at the rear end of the second short-circuited coil set 132.

As described above, the short-circuited coil 13 and the sensing coil 12 can adopt a similar structure. However, as set forth above, the short-circuited coil 13 has fewer turns than the sensing coil 12, such that the short-circuited coil 13 can achieve low impedance.

As described above, the current sensing coil 1 is based on Rogowski coil and has the concentric structure. According to this structural design, the sensing coil 12 and the short-circuited coil 13 are arranged within the shielding layer 11. The short-circuited coil 13 positioned on the inner ring is a low-impedance coil with fewer turns to effectively enhance bandwidth. The sensing coil 12 positioned on the outer ring is a high-sensitivity coil with more turns to effectively enhance sensitivity. Therefore, the current sensing coil 1 meets the needs for both high bandwidth and high sensitivity, while resisting saturation effects to achieve precise measurements under high current conditions. The high-sensitivity sensing coil 12 enables precise current measurement ranging from 1A to 1000A so as to achieve linear and accurate measurement results. The low-impedance short-circuited coil 13 enhances the response capability to transient effects in order to achieve fast and precise measurements of dynamic current fluctuations.

Moreover, the sensing coil 12 of the current sensing coil 1 is designed based on the reverse-parallel structure, where the signal transmission directions between any two adjacent conductors are opposite. This above structure significantly reduces the parasitic capacitance of the sensing coil 12, which can improve the performance in high-frequency applications. Meanwhile, the signal transmission directions between the upper conductor and the lower conductor corresponding thereto are also opposite, which can greatly decrease stray capacitance. This ensures that the sensing coil 12 maintains high accuracy and sensitivity even under strong electromagnetic interference. The reverse-parallel structure further enhances the noise isolation capability of the sensing coil 12, reducing electromagnetic interference and improving the overall performance of the current sensing coil 1. This structural design allows the current sensing coil 1 to be significantly miniaturized while achieving precise AC current measurements. This structural design also improves the performance of wide bandgap (WBG) devices so as to meet the needs of various industries, such as electric vehicles, for WBG components.

The shielding layer 11 of the current sensing coil 1 includes an upper circuit board 111, a lower circuit board 112, and a plurality of connecting poles 113. The upper circuit board 111 is connected to the lower circuit board 112 via these connecting poles 113. The connecting poles 113 are hollow, forming a plurality of through holes. These through holes effectively create a shielding wall around the sensing coil 12 and the short-circuited coil 13, which can provide noise isolation effect. The shielding layer 11 also includes a grounding point 114. The shielding layer 11 is connected to ground GND via this single grounding point 114 with a view to effectively eliminating ground loop noise. The aforementioned shielding wall and single-point grounding structure form an effective shielding mechanism. Based on this structural design, the shielding layer 11 achieves strong isolation capability, significantly optimizing the electromagnetic compatibility (EMC) of the current sensing coil 1.

The current sensing coil 1 can not only be applied to printed circuit boards (PCBs) but also applied to various fields such as power transistors, micro-electro-mechanical systems (MEMS), semiconductor chip packaging, and semiconductor chip processes. Therefore, the current sensing coil 1 is comprehensive in applications and can meet diverse application requirements.

The embodiment just exemplifies the disclosure and is not intended to limit the scope of the disclosure. Any equivalent modification and variation according to the spirit of the disclosure is to be also included within the scope of the following claims and their equivalents.

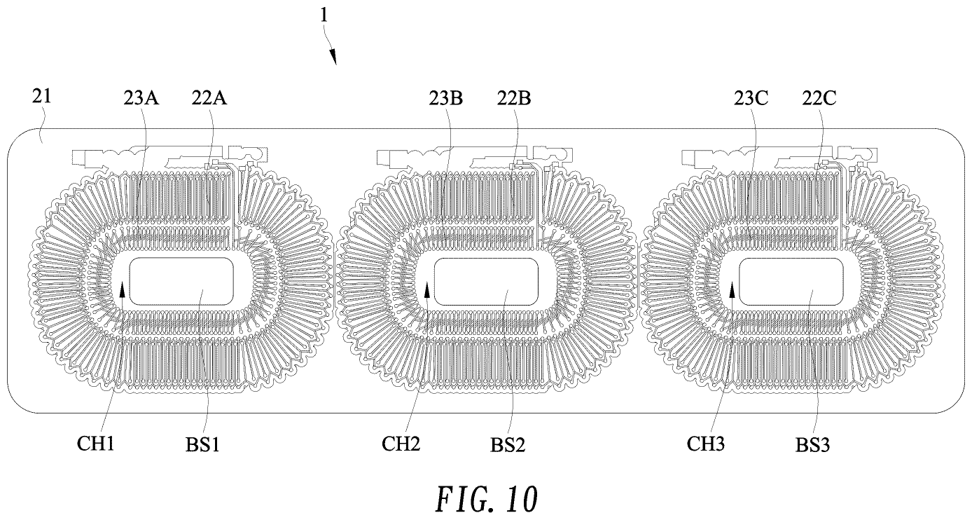

Please refer to FIG. 10, which illustrates a perspective view of a current sensing coil in accordance with another embodiment of the disclosure. As shown in FIG. 10, the current sensing coil 2 in this embodiment is a three-phase current sensing coil, which includes a shielding layer 21, a first sensing coil 22A, a second sensing coil 22B, a third sensing coil 22C, a first short-circuited coil 23A, a second short-circuited coil 23B, and a third short-circuited coil 23C. The current sensing coil 2 is applicable in various devices, such as motor drivers. The structure of the coils in each phase is the same as in the previous embodiment, and the shielding layer 21 is also consistent with that of the previous embodiment.

The shielding layer 21 includes a first central hole CH1, a second central hole CH2, and a third central hole CH3. The first short-circuited coil 23A is disposed within the first central hole CH1. The first sensing coil 22A is disposed within the first central hole CH1. The first sensing coil 22A surrounds the first short-circuited coil 23A, such that the first short-circuited coil 23A is disposed inside the first sensing coil 22A to form a concentric structure. A first conductor BS1 can pass through the center of the first short-circuited coil 23A.

The second short-circuited coil 23B is disposed within the second central hole CH2. The second sensing coil 22B is disposed within the second central hole CH2. The second sensing coil 22B surrounds the second short-circuited coil 23B, such that the second short-circuited coil 23B is disposed inside the second sensing coil 22B, forming a concentric structure. A second conductor BS2 can pass through the center of the second short-circuited coil 23B.

The third short-circuited coil 23C is disposed within the third central hole CH3. The third sensing coil 22C is disposed within the third central hole CH3. The third sensing coil 22C surrounds the third short-circuited coil 23C, such that the third short-circuited coil 23C is disposed inside the third sensing coil 22C to form a concentric structure. A third conductor BS3 can pass through the center of the third short-circuited coil 23C.

Thus, the current sensing coil 2 can perform AC current measurements.

The three-phase coils may generate interference due to mutual inductance, but the shielding wall and single-point grounding structure of the shielding layer 21 can effectively suppress this interference with a view to improving the performance of the current sensing coil 2.

The shapes of the first sensing coil 22A, the second sensing coil 22B, the third sensing coil 22C, the first short-circuited coil 23A, the second short-circuited coil 23B, and the third short-circuited coil 23C can be designed according to the shapes of the first conductor BS1, the second conductor BS2, and the third conductor BS3. For example, in this embodiment, the cross-section of the first conductor BS1 is rectangular, so the first sensing coil 22A and the first short-circuited coil 23A can be designed into a shape similar to an oval, making the centers thereof approximately rectangular to match the shape of the first conductor BS1. In another embodiment, if the cross-section of the first conductor BS1 is circular, the first sensing coil 22A and the first short-circuited coil 23A can be designed into a circular shape, making the centers thereof circular to match the shape of the first conductor BS1.

The embodiment just exemplifies the disclosure and is not intended to limit the scope of the disclosure. Any equivalent modification and variation according to the spirit of the disclosure is to be also included within the scope of the following claims and their equivalents.

To sum up, according to the embodiments of the disclosure, the current sensing coil includes a shielding layer, a sensing coil, and a short-circuited coil. The shielding layer has a central hole. The sensing coil is disposed within the central hole. The short-circuited coil is disposed within the central hole. The sensing coil surrounds the short-circuited coil, such that the short-circuited coil is disposed inside the sensing coil. In addition, the number of turns of the sensing coil is greater than that of the short-circuited coil. The current sensing coil is based on Rogowski coil and has the concentric structure. According to this structural design, the sensing coil and the short-circuited coil are disposed within the shielding layer. The short-circuited coil positioned on the inner ring is a low-impedance coil with fewer turns to effectively enhance bandwidth. The sensing coil positioned on the outer ring is a high-sensitivity coil with more turns to effectively enhance sensitivity. Therefore, the current sensing coil meets the needs for both high bandwidth and high sensitivity, resists saturation effects, and achieves precise measurements under high current conditions. The high-sensitivity sensing coil enables precise current measurement ranging from 1A to 1000A so as to achieve linear and accurate results. The low-impedance short-circuited coil improves response capability to transient effects in order to achieve fast and accurate measurements of dynamic current fluctuations.

Further, according to the embodiments of the disclosure, the sensing coil of the current sensing coil has a unique reverse-parallel structure. The signal transmission directions between any two adjacent conductors are opposite, which can significantly reduce the parasitic capacitance of the sensing coil and improve the performance thereof in high-frequency applications. Meanwhile, the signal transmission directions between the upper conductor and the lower conductor corresponding thereto are also opposite, which can greatly reduce stray capacitance. This ensures that the sensing coil maintains high accuracy and sensitivity even under strong electromagnetic interference. The reverse-parallel structure further enhances the noise isolation effect of the sensing coil, which can decrease electromagnetic interference and improve the overall performance of the current sensing coil. This structural design allows the current sensing coil to be significantly miniaturized while achieving precise AC current measurements. This structural design further improves the performance of wide bandgap (WBG) devices with a view to meeting the needs of various industries, such as electric vehicles, for WBG components.

Moreover, according to the embodiments of the disclosure, the shielding layer of the current sensing coil includes an upper circuit board, a lower circuit board, and a plurality of connecting poles. The upper circuit board is connected to the lower circuit board via these connecting poles. The connecting poles are hollow, which can form a plurality of through holes. These through holes effectively create a shielding wall around the sensing coil and the short-circuited coil to isolate noise. The shielding layer also includes a grounding point, which connects the shielding layer to the ground through this single grounding point in order to effectively eliminate ground loop noise. The aforementioned shielding wall and single-point grounding structure form an effective shielding mechanism. Based on this design, the shielding layer achieves strong isolation capability, significantly enhancing the electromagnetic compatibility (EMC) of the current sensing coil.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A current sensing coil, comprising:
a shielding layer having a central hole;
a sensing coil disposed within the central hole; and
a short-circuited coil disposed within the central hole;
wherein a number of turns of the sensing coil is greater than a number of turns of the short-circuited coil, and the sensing coil surrounds the short-circuited coil, whereby the short-circuited coil is disposed inside the sensing coil.

2. The current sensing coil as claimed in claim 1, wherein the sensing coil surrounds the short-circuited coil to form a concentric structure.

3. The current sensing coil as claimed in claim 1, wherein the number of turns of the sensing coil is 1.3 to 2.5 times the number of turns of the short-circuited coil.

4. The current sensing coil as claimed in claim 1, wherein the sensing coil comprises a first sensing coil set and a second sensing coil set, and the first sensing coil set and the second sensing coil set are intertwined in opposite directions, wherein a front end of the first sensing coil set and a front end of the second sensing coil set are connected to each other, and a rear end of the first sensing coil set is connected to a rear end of the second sensing coil set.

5. The current sensing coil as claimed in claim 1, wherein the sensing coil comprises a first sensing coil set and a second sensing coil set connected to each other, wherein the first sensing coil set comprises a plurality of first coil units connected in series, and the second sensing coil set comprises a plurality of second coil units connected in series.

6. The current sensing coil as claimed in claim 5, wherein each of the first coil units comprises a first upper conductor and a first lower conductor connected to each other, and each of the second coil units comprises a second upper conductor and a second lower conductor connected to each other.

7. The current sensing coil as claimed in claim 6, wherein the first upper conductor of each of the first coil units is adjacent to the second upper conductor of at least one of the second coil units, and the first lower conductor of each of the first coil units is adjacent to the second lower conductor of at least one of the second coil units.

8. The current sensing coil as claimed in claim 6, wherein a current direction of the first upper conductor of each of the first coil units is opposite to a current direction of the first lower conductor thereof, and a current direction of the second upper conductor of each of the second coil units is opposite to a current direction of the second lower conductor thereof.

9. The current sensing coil as claimed in claim 6, wherein a current direction of the first upper conductor of each of the first coil units is opposite to a current direction of the second upper conductor of the second coil unit adjacent thereto, and a current direction of the first lower conductor of each of the first coil units is opposite to a current direction of the second lower conductor of the second coil unit adjacent thereto.

10. The current sensing coil as claimed in claim 1, wherein the shielding layer is grounded via a single grounding point.

11. The current sensing coil as claimed in claim 1, wherein the shielding layer comprises an upper circuit board, a lower circuit board, and a plurality of connecting poles, and the upper circuit board is connected to the lower circuit board via the connecting poles.

12. The current sensing coil as claimed in claim 11, wherein the connecting poles are hollow to form a plurality of through holes.

13. The current sensing coil as claimed in claim 1, wherein the short-circuited coil comprises a first short-circuited coil set and a second short-circuited coil set, and the first short-circuited coil set and the second short-circuited coil set are intertwined in opposite directions, wherein a front end of the first short-circuited coil set and a front end of the second short-circuited coil set are connected to each other, and a rear end of the first short-circuited coil set and a rear end of the second short-circuited coil set are connected to each other.

14. The current sensing coil as claimed in claim 1, wherein the short-circuited coil comprises a first short-circuited coil set and a second short-circuited coil set connected to each other, wherein the first short-circuited coil set comprises a plurality of third coil units connected in series, and the second short-circuited coil set comprises a plurality of fourth coil units connected in series.

15. The current sensing coil as claimed in claim 14, wherein each of the third coil units comprises a third upper conductor and a third lower conductor connected to each other, and each of the fourth coil units comprises a fourth upper conductor and a fourth lower conductor connected to each other.

16. A current sensing coil, comprising:
a shielding layer having a central hole;
a sensing coil disposed within the central hole, wherein the sensing coil comprises a first sensing coil set and a second sensing coil set, and the first sensing coil set and the second sensing coil set are intertwined in opposite directions; and
a short-circuited coil disposed within the central hole;
wherein a front end of the first sensing coil set and a front end of the second sensing coil set are connected to each other, and a rear end of the first sensing coil set is connected to a rear end of the second sensing coil set.

17. The current sensing coil as claimed in claim 16 wherein the first sensing coil set comprises a plurality of first coil units connected in series, and the second sensing coil set comprises a plurality of second coil units connected in series.

18. The current sensing coil as claimed in claim 17, wherein each of the first coil units comprises a first upper conductor and a first lower conductor connected to each other, and each of the second coil units comprises a second upper conductor and a second lower conductor connected to each other.

19. The current sensing coil as claimed in claim 18, wherein the first upper conductor of each of the first coil units is adjacent to the second upper conductor of at least one of the second coil units, and the first lower conductor of each of the first coil units is adjacent to the second lower conductor of at least one of the second coil units.

20. The current sensing coil as claimed in claim 18, wherein a current direction of the first upper conductor of each of the first coil units is opposite to a current direction of the first lower conductor thereof, and a current direction of the second upper conductor of each of the second coil units is opposite to a current direction of the second lower conductor thereof.

21. The current sensing coil as claimed in claim 18, wherein a current direction of the first upper conductor of each of the first coil units is opposite to a current direction of the second upper conductor of the second coil unit adjacent thereto, and a current direction of the first lower conductor of each of the first coil units is opposite to a current direction of the second lower conductor of the second coil unit adjacent thereto.

22. The current sensing coil as claimed in claim 18, wherein the first upper conductor or the first lower conductor of the first coil unit at the front end of the first sensing coil set is connected to the second upper conductor or the second lower conductor of the second coil unit at the front end of the second sensing coil set, and the first upper conductor or the first lower conductor of the first coil unit at the rear end of the first sensing coil set is connected to the second upper conductor or the second lower conductor of the second coil unit at the rear end of the second sensing coil set.

23. The current sensing coil as claimed in claim 22, wherein the first upper conductor of any one of the first coil units not at the front end and the rear end of the first sensing coil set is connected to the first lower conductor of the first coil unit at one side thereof, and the first lower conductor of the first coil unit is connected to the first upper conductor of the first coil unit at another side thereof, wherein the second upper conductor of any one of the second coil units not at the front end and the rear end of the second sensing coil set is connected to the second lower conductor of the second coil unit at one side thereof, and the second lower conductor of the second coil unit is connected to the second upper conductor of the second coil unit at another side thereof.

24. The current sensing coil as claimed in claim 16, wherein the shielding layer is grounded via a single grounding point.

25. The current sensing coil as claimed in claim 16, wherein the shielding layer comprises an upper circuit board, a lower circuit board, and a plurality of connecting poles, and the upper circuit board is connected to the lower circuit board via the connecting poles.

26. The current sensing coil as claimed in claim 25, wherein the connecting poles are hollow to form a plurality of through holes.

27. The current sensing coil as claimed in claim 16, wherein the short-circuited coil comprises a first short-circuited coil set and a second short-circuited coil set, and the first short-circuited coil set and the second short-circuited coil set are intertwined in opposite directions, wherein a front end of the first short-circuited coil set and a front end of the second short-circuited coil set are connected to each other, and a rear end of the first short-circuited coil set and a rear end of the second short-circuited coil set are connected to each other.

28. The current sensing coil as claimed in claim 16, wherein the short-circuited coil comprises a first short-circuited coil set and a second short-circuited coil set connected to each other, wherein the first short-circuited coil set comprises a plurality of third coil units connected in series, and the second short-circuited coil set comprises a plurality of fourth coil units connected in series.

29. The current sensing coil as claimed in claim 28, wherein each of the third coil unit comprises a third upper conductor and a third lower conductor connected to each other, and each of the fourth coil units comprises a fourth upper conductor and a fourth lower conductor connected to each other.

30. The current sensing coil as claimed in claim 16, wherein a number of turns of the sensing coil is greater than a number of turns of the short-circuited coil.

31. The current sensing coil as claimed in claim 16, wherein the sensing coil surrounds the short-circuited coil to form a concentric structure.

32. The current sensing coil as claimed in claim 16, wherein a number of turns of the sensing coil is 1.3 to 2.5 times a number of turns of the short-circuited coil.
